(19) United States
(12) Patent Application Publication
(10) Pub. No.: US 2025/0372432 A1
(43) Pub. Date: Dec. 4, 2025

(54) SUBSTRATE HEATER HAVING REDUCED SURFACE ROUGHNESS

(71) Applicant: Applied Materials, Inc., Santa Clara, CA (US)

(72) Inventors: Jian LI, Fremont, CA (US); Ganesh BALASUBRAMANIAN, Fremont, CA (US); Juan C. ROCHA, San Carlos, CA (US)

(21) Appl. No.: 19/222,475

(22) Filed: May 29, 2025

Related U.S. Application Data
(60) Provisional application No. 63/653,144, filed on May 29, 2024.

(51) Int. Cl. H01L 21/683

(52) U.S. Cl. CPC H01L 21/6833

(57) ABSTRACT

Embodiments of the present disclosure generally relate to systems and methods used in the manufacture of semiconductor devices. More particularly, embodiments of the present disclosure relate to a substrate processing chamber and components thereof for limiting wafer backside damage and methods for the same. In one embodiment, an electrostatic chuck disposed within a processing volume, including a first layer having a first grain size, wherein the first layer is formed of an amorphous material or a nano-crystalline material; and a second layer having a second grain size, wherein the second grain size is greater than the first grain size, wherein the first layer is disposed on the second layer.

### CROSS-REFERENCE TO RELATED APPLICATIONS

This application claims priority to U.S. Provisional Patent Application Ser. No. 63/653,144, filed on May 29, 2024, which is herein incorporated by reference in its entirety.

### BACKGROUND

### Field

Embodiments of the present disclosure generally relate to a substrate support and a method of using the substrate support in semiconductor device manufacturing. More particularly, embodiments relate to an apparatus and method for limiting wafer backside damage and method of manufacturing the same.

### Description of the Related Art

An electrostatic chuck is commonly used for holding a substrate on a substrate support, for example, during deposition of a film layer on the substrate, etching of a film layer on the substrate, implanting ions into the substrate, and other processes used in the manufacture of electronic devices. The electrostatic chuck chucks the substrate by creating an attractive force between the substrate and the electrostatic chuck. A chucking voltage is applied to one or more electrodes in the electrostatic chuck to induce oppositely polarized charges in the substrate and the electrodes. The opposite charges pull the substrate and the electrostatic chuck together, thus fixing the substrate in place.

Damage to the backside of the substrate may occur during chucking due to the rough surface of the electrostatic chuck. The damage may be further exacerbated when large chucking forces are applied to the substrate. For example, the backside of the substrate can be damaged as a result of thermal expansion during and after chucking at locations of direct contact between the substrate and the electrostatic chuck. The backside of substrates may be used for optical focus and lithography; thus, when the backside of the substrate is damaged, the quality of the substrate is decreased.

Thus, there is a need for an improved electrostatic chuck for securing a substrate during substrate processing.

### SUMMARY

Embodiments of the present disclosure generally relate to systems and methods used in the manufacture of semiconductor devices. More particularly, embodiments of the present disclosure relate to a substrate processing chamber and components thereof for limiting wafer backside damage and methods of manufacturing the same. In one embodiment, an electrostatic chuck disposed within a processing volume, comprising a first layer having a first grain size, wherein the first layer is formed of an amorphous material or a nano-crystalline material; and a second layer having a second grain size, wherein the second grain size is greater than the first grain size, wherein the first layer is disposed on the second layer is provided. The first layer is formed from an aluminum containing material.

In another embodiment, an electrostatic chuck, comprising a chuck body comprising a top layer and a bulk layer, the top layer disposed on the bulk layer, wherein the top layer comprises an amorphous material or a nano-crystalline material, and the top layer has a surface roughness of less than 40 pin is provided.

In yet another embodiment, a method of manufacturing an electrostatic chuck, comprising forming, from a first powder, a first ceramic layer having a first grain size; forming, from a second powder, a second ceramic layer having a second grain size; and bonding the first ceramic layer to the second ceramic layer via diffusion bonding, wherein the first powder and the second powder include aluminum.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of an exemplary processing chamber having an electrostatic chuck disposed therein, according to one or more embodiments.

FIG. 2 illustrates a schematic cross-sectional view of the exemplary processing chamber of FIG. 1 showing a substrate disposed on an electrostatic chuck during processing thereof, according to one or more embodiments.

FIG. 3 illustrates an enlarged cross-sectional view of an electrostatic chuck, according to one or more embodiments.

FIG. 4 illustrates a flow chart of a method of manufacturing an electrostatic chuck, according to one or more embodiments.

FIG. 5A illustrates a flow chart of a method of manufacturing an electrostatic chuck, according to one or more embodiments.

FIG. 5B illustrates a schematic cross-sectional view of an electrostatic chuck, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure relate to an improved electrostatic chuck for use in a processing chamber to fabricate semiconductor devices. More particularly, an apparatus and method for limiting substrate backside damage and method of manufacturing the same.

Wafer backsides may be used for optical focus and lithography; thus, when the backside is damaged, the quality of the wafer is decreased. Damage to the backside may be caused when the wafer is chucked onto a rough heater surface (i.e. a heater with a large grain size), the damage is further exacerbated by wafer thermal expansion and high chucking force when overcoming wafer bowing. While use of crystalline or micro-crystalline materials in the heater, which have a large grain size, benefits thermal conductivity, the large grain size damages the backside of wafers. By using two different materials in a top layer and a bottom layer (e.g. a bulk layer) during heater manufacture wafer backside damage is reduced. The top layer, on which the substrate is disposed, is a thin amorphous or nano-crystalline layer. Whereas, the bulk layer is a crystalline or micro-crystalline material (e.g. aluminum nitride (AlN)) having high thermal conductivity to improve thermal uniformity. Use of a thin layer of amorphous material as the top layer mitigates wafer backside damage, while the crystalline or micro-crystalline material of the bulk layer maintains a uniform heater temperature.

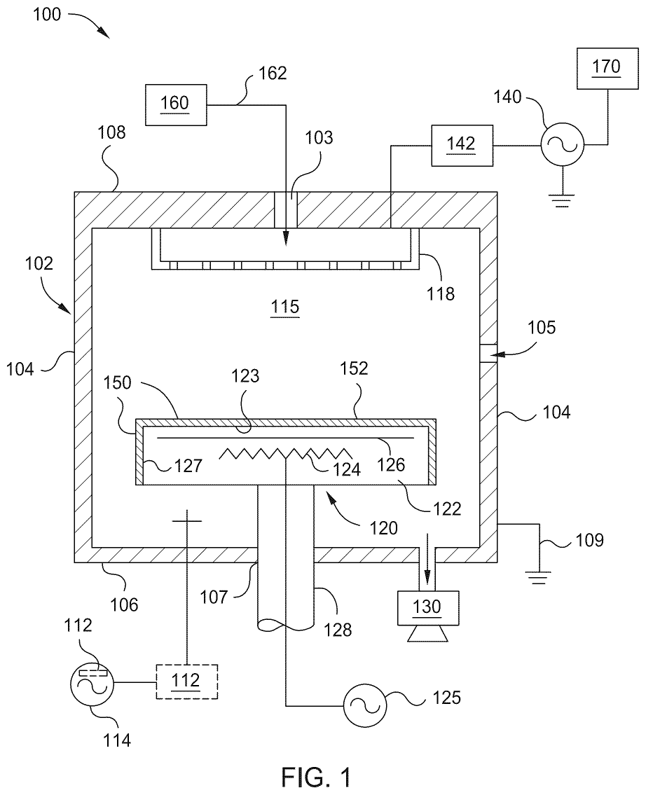

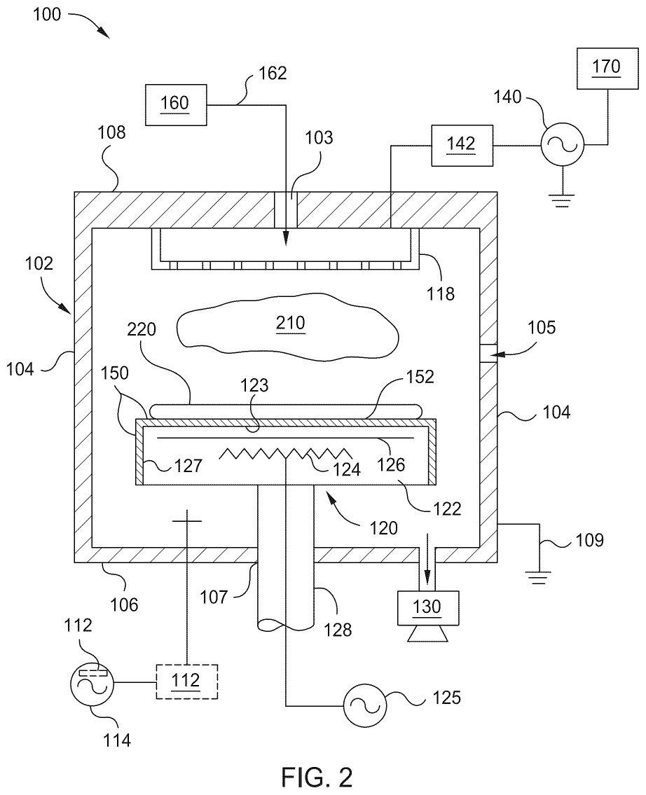

FIG. 1 illustrates a schematic cross-sectional view of a processing chamber 100, having an electrostatic chuck 120 according to one embodiment of the disclosure. FIG. 2 illustrates a schematic cross-sectional view of the chamber 100 of FIG. 1 depicting the substrate 220 disposed on the electrostatic chuck 120. The processing chamber 100 may be a chemical vapor deposition (CVD) chamber as shown, or other suitable plasma processing chamber. Examples of a processing chamber 100 that may be adapted to benefit from the disclosure include plasma-enhanced chemical vapor deposition (PECVD) chambers. It is contemplated that processing chambers from other manufacturers may also be adapted to benefit from the embodiments described herein. Although FIG. 1 described herein is illustrative of a PECVD chamber, the processing chamber 100 should not be construed or interpreted as limiting the scope of the embodiments described herein. The embodiments described herein can be equally applied to apparatus utilized for physical vapor deposition (PVD), etching, implanting, annealing, and plasma-treating materials on semiconductor substrates, among others.

As illustrated in FIG. 1, the processing chamber 100, shown schematically, includes a chamber body 102. The chamber body 102 has sidewalls 104, a bottom wall 106, and a chamber cover 108. The sidewalls 104, the bottom wall 106, and the cover 108 may be formed from conductive materials, such as aluminum, stainless steel, or alloys and combinations thereof. The sidewalls 104 and the bottom wall 106 are coupled to an electrical ground 109 when the processing chamber 100 is a plasma processing chamber. The chamber cover 108, the sidewalls 104, and the bottom wall 106 define a processing volume 115 therein. The sidewalls 104 include a substrate transfer port 105 to facilitate transfer of substrates 220 into and out of the processing volume 115. The substrate transfer port 105 may be coupled to a transfer chamber (not shown) and/or other chambers of a substrate processing system (not shown).

The dimensions of the chamber body 102 and related components of the processing chamber 100 are not limited and generally are proportionally larger than the size of the substrate 220 to be processed therein. The substrate 220 may be sized to have a diameter of 200 mm or less, 300 mm, and 450 mm or larger depending upon the desired implementation.

A gas panel 160 is fluidly connected by a conduit 162 to the processing volume 115 to provide one or more precursor gases or other process gases to the processing chamber 100. The conduit 162 is connected to an opening 103 through the chamber cover 108. A pump 130 is fluidly connected to the processing volume 115 to pump out the process gases and to maintain vacuum conditions within the processing volume 115 during substrate processing. The pump 130 may be a conventional roughing pump, roots blower, turbo pump, or other similar device that is adapted control the pressure in the processing volume 115 to a desired level.

A showerhead 118 is coupled to the chamber cover 108 and located above the electrostatic chuck 120 in the processing volume 115. The showerhead 118 is configured to introduce one or more precursor gases into the processing volume 115 of the processing chamber 100. The showerhead 118 also functions as an electrode for coupling RF power to the process gases introduced into the processing volume 115. The process gases from the gas panel 160 enter the processing volume 115 through the showerhead 118.

As illustrated in FIG. 2, an RF power source 140 is coupled to the showerhead 118 through an impedance matching circuit 142. The RF power source 140 is configured to provide the power necessary for striking and sustaining the plasma 210 formed from the gases within the processing volume 115. The operation of the RF power source 140 is controlled by a controller 170 that also controls the operation of other components in the processing chamber 100.

The electrostatic chuck 120 is disposed within the processing volume 115. The electrostatic chuck 120 is supported on a hollow stem 128 and includes a chuck body 122 coupled to the stem 128. The stem 128 is connected to an opening 107 through the bottom wall 106 sealed by, for example, a flexible bellows (not shown). The chuck body 122 electrostatically chucks the substrate 220 disposed thereon during processing of the substrate in the processing chamber 100. The chuck body 122 is formed from a dielectric material, for example a ceramic material, such as aluminum nitride (AlN) among other suitable materials. The electrostatic chuck 120 has a top surface 123 and a side surface 127.

The chuck body 122 includes a heater 124 embedded therein. The heater 124 is coupled to a power source 125. The heater 124 may be a resistive heating element, an inductive heating element, or other suitable heater. The heater 124 is configured to heat the electrostatic chuck 120 and the substrate 220 during processing to a temperature between about 100 degrees Celsius and about 700 degrees Celsius. The electrostatic chuck 120 may also be actively cooled, such as by flowing a coolant through cooling channels (not shown) therein. By actively balancing the heat input from the heater 124 and the cooling of the coolant, the temperature of the electrostatic chuck 120 and the substrate 220 placed thereon can be closely controlled.

A temperature sensor (not shown), such as but not limited to a thermocouple, may be connected to the chuck body 122 to measure the temperature of the electrostatic chuck 120. The temperature sensor is configured to communicate a signal indicative of the temperature of the chuck body 122 to a temperature controller (not shown) which provides a control signal to the power source 125 to change the power supplied to the heater, or change the flow rate, temperature, or both of the coolant, when the heat input or loss related thereto changes.

A chucking electrode 126 is embedded within the chuck body 122 of the electrostatic chuck 120. The chucking electrode 126 is connected to a power source 114 through an isolation transformer 112 disposed between the power source 114 and the chucking electrode 126. The isolation transformer 112 may be part of the power source 114, or be separate from the power source 114, as shown by the dashed lines in FIG. 1. The power source 114 is configured to apply a chucking voltage between about 50 VDC and about 5000 VDC to the chucking electrode 126 of the electrostatic chuck 120 to chuck the substrate 220. The power source 114 may communicate with a controller (not shown) configured to control the operation of the chucking electrode 126 by selecting the current value supplied to the chucking electrode 126 for chucking and de-chucking of the substrate 220.

In various embodiments, a seasoning layer 150 is deposited at least on the top surface 123 of the chuck body 122 before the substrate 220 is transferred into the processing chamber 100 through the substrate transfer port 105. In some embodiments, the seasoning layer 150 is a layer of silicon nitride, silicon carbon nitride, silicon oxycarbide, silicon oxide, or nitrogen-doped carbon having a thickness between about 100 nm and about 20 microns. The seasoning layer 150 is deposited using silicon containing precursors, carbon containing precursors, and/or nitrogen containing precursors. Examples of silicon containing precursors include silane (SiH4), tetraethyl orthosilicate (TEES), di-methyl-silane (DMS), and tri-methyl-silane (TMS), among others. Examples of carbon containing precursors include propylene, acetylene, ethylene, methane, hexane, hexane, isoprene, and butadiene, among others. Examples of nitrogen containing precursors include pyridine, aliphatic amine, amines, nitriles, ammonia, among others. The seasoning layer 150 is uniformly deposited by a chemical vapor deposition process as discussed herein, or in a separate process when removed from the chamber, including by a spray process, a dipping process, a thermal process, or other suitable manner.

After the seasoning layer 150 is deposited over at least the top surface 123 of the electrostatic chuck 120 and optionally over the side surface 127 of the electrostatic chuck 120, a substrate 220 is transferred into the chamber 100 through the substrate transfer port 105 and placed on a top surface 152 of the seasoning layer 150. At temperatures above 500 degrees Celsius, charges are trapped at the interface between the seasoning layer 150 and the substrate 220. Charge trapping inhibits current leakage from the chucking electrode 126 to the substrate 220, and thus reduces the chucking voltage utilized to generate sufficient chucking force for chucking the substrate 220 to the electrostatic chuck 120.

The dielectric constant of the seasoning layer 150 can be tuned between about 3 and about 12 to enable controlled charge trapping and modification of the chucking force at temperatures greater than 500 degrees Celsius. The seasoning layer 150 may be doped with trace amounts of carbon using a carbon-containing precursor gas in the processing chamber 100 such that the resultant doped seasoning layer 150 has charge-leaking behavior yet low physical hardness. By modulating the content of carbon therein, the seasoning layer 150 can be fabricated to provide sufficient charge trapping and physically cushioned support to the substrate 220. As a result, when the substrate 220 is processed at high temperatures such as at or above 500 degrees Celsius, backside damage to the substrate 220, or particle generation, due to direct contact and movement over the top surface 123 of the electrostatic chuck 120 can be minimized or eliminated by the cushioning supplied by the seasoning layer 150. Thus, the deposition of the seasoning layer 150 enables the electrostatic chuck 120 to substantially flatten and sufficiently secure the substrate 220 thereon and reduce backside damage on the substrate 220, while enabling the application of a reduced chucking voltage.

The performance of the seasoning layer 150 can be evaluated based on the seasoning layer's refractive index, modulus/hardness, temperature-dependent leakage current, and chucking behavior. The refractive index provides information about the composition of the seasoning layer 150, the modulus/hardness provides information about the mechanical strength of the seasoning layer 150, the leakage current provides information about the charge-trapping effectiveness of the seasoning layer 150, and the chucking behavior provides information about how well the substrate 220 can be chucked by the electrostatic chuck 120 through the seasoning layer 150.

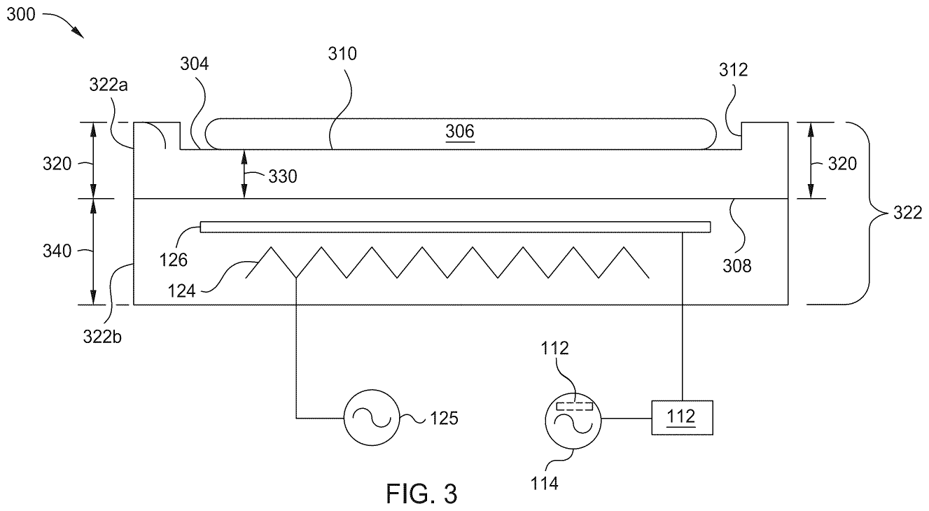

FIG. 3 illustrates an enlarged cross-sectional view of an electrostatic chuck 300. In some embodiments, the electrostatic chuck body 322 is the electrostatic chuck body 122 of FIG. 1. The electrostatic chuck body 322 further includes a top layer 322a and a bulk layer 322b. In operation, a substrate 306 is disposed on a top surface 304 of the top layer 322a, where a backside 310 of the substrate 306 is in contact with the top surface 304 of the top layer 322a.

The top layer 322a is disposed on the top surface 308 of the bulk layer 322b. In some embodiments, the top layer 322a is formed from an amorphous or nano-crystalline material, such as AlN, AlO, AlON, AISIN, aluminum silicate (Al₂SiO₅), AIG, or other suitable materials. It is contemplated that other suitable materials for the top layer 322a are those having a surface roughness of less than 40 pin, such as less than 10 pin, such as less than 4 pin (0.1 micron), such as less than 2 pin (0.05 micron). It is also contemplated that other suitable materials for the top layer 322a are those having a resistivity range that is suitable for Johnsen-Rahbek (JR) chucking at operating temperatures, such as between about 1E8 ohm*cm and about 1E11 ohm*cm at an operating temperature between about 300° C. and about 700° C. It is further contemplated that other suitable materials for the top layer 322a are those providing an expansion coefficient between about 3E-6° C.⁻¹ and about 10E-6° C.⁻¹, such as about 5E-6° C.⁻¹. In some embodiments, the top layer 322a has a rim thickness 320 (i.e., a thickness of a rim portion of the top layer 322a) between about 0.5 mm and about 2 mm, such as about 1 mm to about 1.3 mm, such as 1 mm. In some embodiments, the top layer 322a has a feature, such as a pocket. In some embodiments, a thickness 330 of the feature/pocket is between about 0.7 mm to about 1 mm. In some embodiments, feature wall 312 is slanted or angled inward towards the top surface 304 of the top layer 322a. By decreasing the surface roughness of the top surface 304 of the top layer 322a, less damage occurs to the backside 310 of the substrate 306 during processing.

In some embodiments, the bulk layer 322b is formed from a dielectric material, for example, a ceramic material, such as aluminum nitride (AlN) among other suitable materials. In some embodiments, the bulk layer 322b comprises by mass between about 90% and about 99% of aluminum nitride, such as about 95% aluminum nitride. In some embodiments, the bulk layer 322b is doped with magnesium (Mg) or yttrium (Y) to control the resistivity at certain temperatures. It is contemplated that other suitable materials for the bulk layer 322b are those having a crystalline structure with high thermal conductivity, such as between about 100 W/m*K and about 180 W/m*K, at room temperature (e.g. between about 20° C. and about 25° C.). In some embodiments, the bulk layer 322b has a thickness 340 between 10 mm to 25 mm, such as about 18 mm.

A chucking electrode 126 is embedded within the bulk layer 322b of the chuck body 322. The chucking electrode 126 is connected to a power source 114 through an isolation transformer 112 disposed between the power source 114 and the chucking electrode 126. The isolation transformer 112 may be part of the power source 114, or may be separate from the power source 114, as shown by the dashed lines in FIG. 1. The power source 114 is configured to apply a chucking voltage between about 50 V_{DC} and about 5000 V_{DC} to the chucking electrode 126 of the electrostatic chuck 120 to chuck the substrate 306. The power source 114 may communicate with a controller (not shown) configured to control the operation of the chucking electrode 126 by selecting the current value supplied to the chucking electrode 126 for chucking and de-chucking of the substrate 306. The electrostatic chuck 300 further includes a heater 124 embedded in the bulk layer 322b of the chuck body 322. The heater 124 is coupled to a power source 125. The heater 124 may be a resistive heating element, an inductive heating element, or other suitable heater. The heater 124 is configured to heat the electrostatic chuck body 322 and the substrate 306 during processing to a temperature between about 100 degrees Celsius and about 700 degrees Celsius. The chuck body 322 may also be actively cooled, such as by flowing a coolant through cooling channels (not shown) therein. By actively balancing the heat input from the heater 124 and the cooling of the coolant, the temperature of the electrostatic chuck body 322 and the substrate 306 placed thereon can be closely controlled.

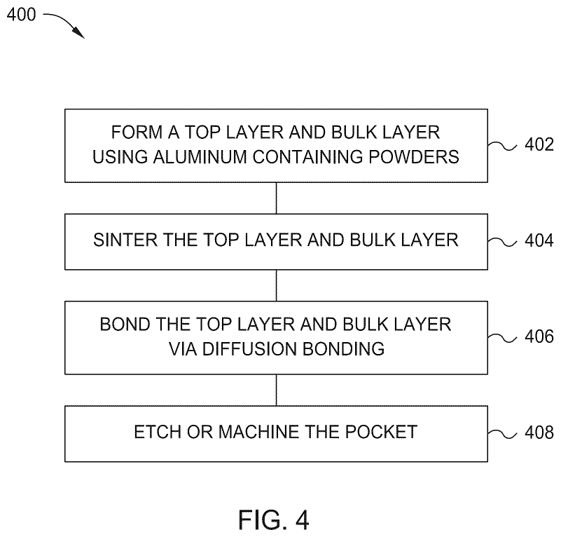

FIG. 4 illustrates a flow chart of a method of manufacturing an electrostatic chuck 400, such as the electrostatic chuck 300 of FIG. 3. At operation 402, a top layer (e.g. top layer 322a of FIG. 3) and a bulk layer (e.g. bulk layer 322b of FIG. 3) are formed using ceramic powders. In some embodiments, the ceramic powders are an aluminum-containing powder. In some embodiments, the aluminum-containing powder contains aluminum nitride (AlN). The top layer is formed by molding a first ceramic powder (e.g. AlN powder) having a first grain size into a desired shape. The bulk layer is formed by molding a second powder (e.g. AlN powder) having a second grain size into a desired shape. The second grain size is greater than the first grain size. In various embodiments, the top layer formed from the first ceramic powder is amorphous or nano-crystalline. In various embodiments, the bulk layer formed from the second ceramic powder is crystalline or micro-crystalline.

At operation 404, the top layer is sintered to the bulk layer. In some embodiments, the top layer and bulk layer are sintered at sintering temperature between 1800° C. to 2000° C. At operation 406, the top layer and bulk layer are bonded via diffusion bonding. In some embodiments, the top layer and bulk layer are diffusion bonded at a bonding temperature between 1300° C. to 1600° C. At operation 408, a surface of the top layer may be chemically etched or machined to form a feature, such as a pocket, in which a substrate (e.g., a wafer) can be disposed.

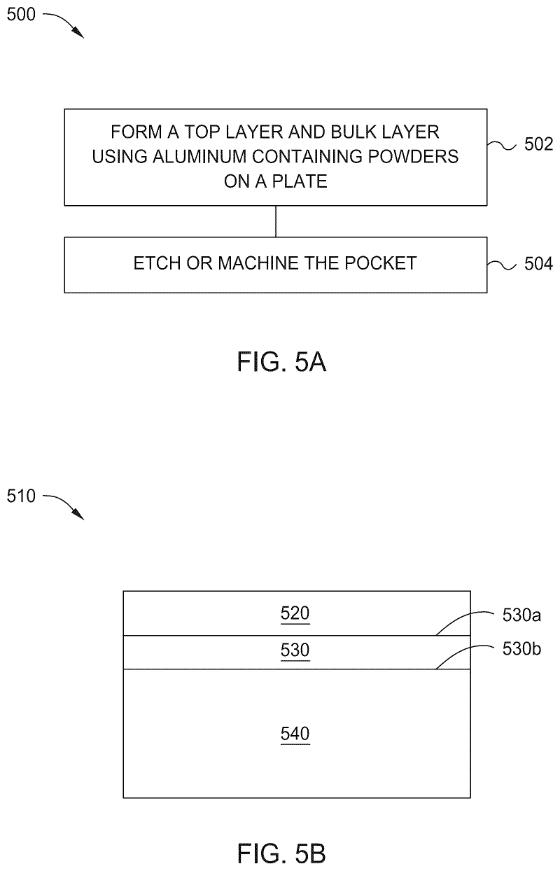

FIG. 5A illustrates a flow chart of a method of manufacturing an electrostatic chuck, according to one or more embodiments. FIG. 5B illustrates a schematic cross-sectional view of an electrostatic chuck, according to one or more embodiments. The following description refers simultaneously to both the method 500 of manufacturing the electrostatic chuck and the cross-sectional view of FIG. 5B. In various embodiments, the method 500 is implemented via instructions stored in the memory of a controller (e.g. controller 170 of FIG. 1), which, when executed by the controller (e.g. including a CPU or ASIC), performs the method 500 to manufacture the electrostatic chuck 510 illustrated in FIG. 5B.

Electrostatic chuck 510 includes a top layer 520, a plate 530, and a bulk layer 540. At operation 502, electrostatic chuck 510 is formed by sintering the top layer 520 and bulk layer 540 onto a first side 530a and second side 530b of a plate 530. Plate 530 may be used when the coefficient of thermal expansion (CTE) between the top layer 520 and bulk layer 540 are too different. Plate 530 may act as a buffer material (e.g., a buffer layer) with a different dopant than top layer 520 and bulk layer 540, and may comprise of any suitable material. The top layer 520 and bulk layer 540 are formed from a first and second ceramic powder having a first and second grain size, respectively. In some embodiments, the ceramic powders are an aluminum-containing powder. In some embodiments, the aluminum-containing powder is an aluminum nitride (AlN) powder. The top layer 520 has the first grain size, and the bulk layer has the second grain size. In various embodiments, the second grain size is greater than the first grain size. In various embodiments, the top layer 520 formed from the first ceramic powder is amorphous or nano-crystalline. In various embodiments, the bulk layer 540 formed from the second ceramic powder is crystalline or micro-crystalline. At operation 504, a surface of the top layer may be chemically etched or machined to form a feature, such as a pocket, in which a substrate (e.g. wafer) can be disposed.

In one embodiment, an electrostatic chuck disposed within a processing volume, comprises a first layer having a first grain size, wherein the first layer is formed of an amorphous material or a nano-crystalline material; and a second layer having a second grain size, wherein the second grain size is greater than the first grain size, wherein the first layer is disposed on the second layer. The first layer is formed from an aluminum containing material. The first layer has surface roughness of less than 40 pin. The first layer has surface roughness of less than 10 μin. The second layer is formed from an aluminum containing material. The aluminum containing material is one or more of AlN, AlO, AlON, AISIN, aluminum silicate (Al₂SiO₅), and/or AIG. The aluminum containing material is aluminum nitride (AlN). The first layer has a rim thickness of less than 1.3 mm. The first layer further comprises a pocket, wherein the pocket has a pocket thickness of less than 0.8 mm. The first layer comprises one or more of AlN, AlO, AlON, AISIN, aluminum silicate (Al₂SiO₅), and/or AIG. A buffer layer is disposed between the first layer and the second layer.

In another embodiment, an electrostatic chuck, comprises a chuck body comprising a top layer and a bulk layer, the top layer disposed on the bulk layer, wherein the top layer comprises an amorphous material or a nano-crystalline material, and the top layer has a surface roughness of less than 40 pin. The top layer has a first grain size, and the bulk layer has a second grain size that is greater than the first grain size. The top layer has a resistivity between 1E8 ohm*cm and 1E11 ohm*cm. The top layer comprises one or more of AlN, AlO, AlON, AISIN, aluminum silicate (Al₂SiO₅), and/or AIG. The bulk layer comprises aluminum nitride (AlN). The top layer has a rim thickness of less than 1.3 mm. The top layer has a pocket thickness of less than 0.8 mm.

In yet another embodiment, a method of manufacturing an electrostatic chuck, comprises forming, from a first powder, a first ceramic layer having a first grain size; forming, from a second powder, a second ceramic layer having a second grain size; and bonding the first ceramic layer to the second ceramic layer via diffusion bonding, wherein the first powder and the second powder include aluminum. The first grain size is less than the second grain size, the first grain size being less than 40 μin. Etching or machining a feature extending a depth from a surface of the first ceramic layer, wherein the feature depth extends less than 1 mm.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Embodiments of the present disclosure generally relate to substrates for electronic devices and to methods of forming substrates. Substrates described herein can have superior device performance relative to conventional technologies. Methods described herein are reproducible and can yield uniform passivation layers. Further, embodiments described herein can enable, for example, streamlined material handling and integration and longer shelf life for the passivated substrates (passivated film rolls) than conventional technologies.

As is apparent from the foregoing general description and the specific aspects, while forms of the aspects have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, process operation, process operations, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, process operation, process operations, element, or elements and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a layer” includes aspects comprising one, two, or more layers, unless specified to the contrary or the context clearly indicates only one layer is included.

While the foregoing is directed to aspects of the present disclosure, other and further aspects of the disclosure may be devised without departing from the basic scope thereof, and the scope thereof is determined by the claims that follow.

What is claimed is:

1. An electrostatic chuck, comprising:
a first layer having a first grain size, wherein the first layer is formed of an amorphous material or a nano-crystalline material; and
a second layer disposed on the first layer and having a second grain size, wherein the second grain size is greater than the first grain size.

2. The electrostatic chuck of claim 1, wherein the first layer is formed from an aluminum containing material.

3. The electrostatic chuck of claim 1, wherein the first layer has a surface roughness of less than 40 pin.

4. The electrostatic chuck of claim 3, wherein the first layer has a surface roughness of less than 10 pin.

5. The electrostatic chuck of claim 1, wherein the second layer is formed from an aluminum containing material.

6. The electrostatic chuck of claim 5, wherein the aluminum containing material is one or more of AlN, AlO, AlON, AISIN, aluminum silicate (Al₂SiO₅), and/or AIG.

7. The electrostatic chuck of claim 5, wherein the aluminum containing material comprises aluminum nitride (AlN).

8. The electrostatic chuck of claim 1, wherein the first layer has a rim thickness of less than 1.3 mm.

9. The electrostatic chuck of claim 1, wherein the first layer further comprises a pocket, and the pocket has a pocket thickness of less than 0.8 mm.

10. The electrostatic chuck of claim 1, wherein the first layer comprises one or more of AlN, AlO, AlON, AISIN, aluminum silicate (Al₂SiO₅), and AIG.

11. The electrostatic chuck of claim 1, wherein a buffer layer is disposed between the first layer and the second layer.

12. An electrostatic chuck, comprising:
a chuck body comprising a top layer and a bulk layer, the top layer disposed on the bulk layer, wherein the top layer comprises an amorphous material or a nano-crystalline material, and the top layer has a surface roughness of less than 40 pin.

13. The electrostatic chuck of claim 12, wherein the top layer has a first grain size, and the bulk layer has a second grain size that is greater than the first grain size.

14. The electrostatic chuck of claim 12, wherein the top layer has a resistivity between 1E8 ohm*cm and 1E11 ohm*cm.

15. The electrostatic chuck of claim 12, wherein the top layer comprises one or more of AlN, AlO, AlON, AISIN, aluminum silicate (Al₂SiO₅), and AIG.

16. The electrostatic chuck of claim 12, wherein the bulk layer comprises aluminum nitride (AlN).

17. The electrostatic chuck of claim 12, wherein the top layer has a rim thickness of less than 1.3 mm.

18. The electrostatic chuck of claim 12, wherein the top layer has a pocket thickness of less than 0.8 mm.

19. A method of manufacturing an electrostatic chuck, comprising:
forming, from a first powder, a first ceramic layer having a first grain size;
forming, from a second powder, a second ceramic layer having a second grain size; and
bonding the first ceramic layer to the second ceramic layer via diffusion bonding, wherein the first powder and the second powder comprise aluminum.

20. The method of claim 19, wherein the first grain size is less than the second grain size, the first grain size being less than 40 pin.

21. The method of claim 19, further comprises etching or machining a feature extending a depth from a surface of the first ceramic layer, wherein the depth extends less than 1 mm.
